(19) United States
(12) Patent Application Publication
(10) Pub. No.: US 2009/0172493 A1
(43) Pub. Date: Jul. 2, 2009

(54) METHOD AND DEVICE FOR DECODING LOW DENSITY PARITY CHECK CODE

(75) Inventors: Beom-Jin PARK, Suwon-si (KR); Congchong RU, Beijing (CN); Dan WANG, Beijing (CN); Lijun WEI, Beijing (CN); Sung-Jin PARK, Seoul (KR)

Correspondence Address: Jefferson IP Law, LLP, 1730 M Street, NW, Suite 807, Washington, DC, 20036, US

(73) Assignees: SAMSUNG ELECTRONICS CO. LTD., Suwon-si (KR); BEIJING SAMSUNG TELECOM R & D CENTER, Beijing (CN)

(21) Appl. No.: 12/342,945

(22) Filed: Dec. 23, 2008

(30) Foreign Application Priority Data
Dec. 28, 2007 (CN) 200710307835.1

(51) Int. Cl. H03M 13/05; G06F 11/07

(52) U.S. Cl. 714/752; 714/E11.021

(57) ABSTRACT

An apparatus for decoding a Low Density Parity Check (LDPC) is provided. The apparatus includes a variable node message memory for storing a variable node message vector, a controller for controlling a node computing unit to read from and write to the variable node message memory and controlling an iteration process for the apparatus, and a node computing unit for updating a check node message and a variable node message, and determining a hard decision message, the node computing unit includes a variable node message generation unit for determining the variable node message for use in a check node message calculation unit according to the variable node message vector, a check node message calculation unit for updating the check node message, a variable node message updating unit for updating a corresponding variable node message, a hard decision calculation unit for determining the hard decision message for a corresponding variable node, and a parity check unit for determining a parity bit and outputting the parity bit to a decoding termination controller.

### PRIORITY

This application claims the benefit under 35 U.S.C. §119(a) of a Chinese patent application filed on Dec. 28, 2007 in the Chinese Patent Office and assigned Serial No. 200710307835.1, the entire disclosure of which is hereby incorporated by reference.

### BACKGROUND OF THE INVENTION

1. Field of the Invention

The present invention relates to an encoding and decoding technology for a digital communication system. More particularly, the present invention relates to a method and device for decoding a Low Density Parity Check (LDPC) code.

2. Description of the Related Art

For a communication system, channel coding technology guarantees reliable communication in a channel that includes noise. Presently, modern coding techniques, such as Turbo coding, Low Density Parity Check (LDPC) coding and the like have been applied in some communication standards for forward error correction. In the Institute of Electrical and Electronics Engineers (IEEE) 802.16e mobile Worldwide Interoperability for Microwave Access (WiMAX) standard, both Turbo coding and LDPC coding are simultaneously used as a Forward Error Correction (FEC) code. Moreover, LDPC coding is used as channel coding in systems such as a Digital Video Broadcasting Satellite version 2 (DVB-S2), the Digital Television Terrestrial Broadcasting (DVB-T) system proposed by Tsinghua University and the Mobile Multimedia Broadcasting (CMMB) system proposed by TiMi corporation.

Since LDPC coding has superior error correction performance and lower decoding complexity, LDPC coding can be more effective than Turbo coding. When designing an LDPC decoding process, a parallel stage must be specified for the LDPC decoder. The parallel stage may include a block-level parallel structure and a sub-block-level parallel structure. Also, message storing during an iterative decoding process must be considered. In a conventional Belief Propagation (BP) algorithm, a current iteration operation utilizes a previous iteration result. Therefore, all iteration messages are necessary to be stored. However, in the BP algorithm, based on a variable node message vector (VN_M [3]) and the BP algorithm, based on a check node central (CN_C), a message is updated in a trigger schedule.

Accordingly, a previous iteration result may not be stored. Therefore, a reduced amount of memory for messages will be utilized for the BP algorithm. In addition, a necessary number of iterations for decoding is an important characteristic of the LDPC decoder. With the conventional BP algorithm, a necessary number of iterations for decoding is generally within a range from 30 to 50, depending on performance requirements. To obtain substantially the same performance, the necessary number of iterations for decoding with the CN_C BP algorithm is approximately half the number of iterations in the conventional BP algorithm. Further, decoding complexity for the check nodes must be reduced.

To implement decoding in parallel, it is necessary that a check matrix for an LDPC code has a special structure. The WiMax system and the DVB-T system use a quasi-cyclic LDPC code, which is based on a cyclic matrix. In the DVB-S2 system and a CMMB system, the structure applied to the LDPC code is more stochastic. The LDPC code is constructed based on a base matrix and certain expandable rules and includes potential parallel attributes. A number of parallel branches for the decoder and a procedure for message storing and updating are determined according to the structure of a check matrix for the LDPC code and the system throughput.

The conventional BP algorithm and the CN_C BP algorithm are described below in FIG. 1. The BP algorithm, as shown in FIG. 1, includes two-sections. The two-sections include two sets of nodes. One set of nodes is a variable node set corresponding to a code word bit, as shown in 101. Another set of nodes is a check node set corresponding to a constraint relationship, as shown in 102.

In 103, M(n) is the set of check nodes connecting to variable node n, wherein (0≦n≦N−1) (e.g., M(3)={1,2}. In 104 N(m) is the set of variable nodes operated in the m^{th} check equation, wherein (0≦m≦M−1) (e.g., N(3)={4,5,6,7}. Also, M(n)\m is set for the rest of M(n) elements from which m elements are deleted. Similarly, N(m)\n is set for the rest of N(m) elements from which n elements are deleted. In addition, q_{n→m}(0) (q_{n→m}(1)) is a condition probability in which information transmitted from the variable node n to the check node m indicates the variable node n is 0 or 1 based on the set M(n)\m. Similarly, rm→n (0) (rm→n (1)) is a condition probability in which information transmitted from the check node m to the variable node n indicates that the variable node n is 0 or 1 based on a set N(m)→n. Finally, a transmitting vector and the receiving vector includes x=(x₀, x₁, . . . , x_{N-1}) and y=(y₀, y₁, . . . , y_{N-1}), respectively.

In a probability domain, inputs of a BP decoding algorithm are A Posteriori Probabilities (APP). That is, q_{n→m}(0)=P_{x/y}(xₙ=0|yₙ) and q_{n→m}(1)=P_{x/y}(xₙ=1|yₙ), both of which are determined according to channel statistic characteristics. In addition, the Log Likelihood Ratio (LLR) is defined as LLRs z_{n→m}(xₙ)≡ log(q_{n→m}(0)/q_{n→m}(1)) (variable message 105, that is, V_M) and L_{n→m} (xₙ)≡ log(r_{m→n}(0)/r_{m→n}(1)) (check message 106).

By a hyperbolic tangent rule, a conventional BP algorithm may be described as follows:

Initialization:

Suppose each variable node n has a posteriori probability of L(xₙ|yₙ)=log(P(xₙ=0|yₙ)/P(xₙ=1|yₙ)) (which refers to channel information Ch_M) and 3z_{n→m}(xₙ)=L(xₙ″yₙ), m [symbol] M(n).

Message Updating:

Step 1: (a check node updating): for each check node m and n [symbol] N(m), calculating

L_{m→n}(xₙ)=[Π_{n′} [symbol] _{N(m)\n} sign(z_{n′→m}(xₙ))]×2 tanh⁻¹ [Π_{n′} [symbol] _{N(m)\n}tanh(|z_{n′→m}(xₙ)|/2)] (1)

Step 2: (a variable node updating): for each variable node n, calculating

z_{n→m}′(zₙ)=L(xₙ|yₙ)+Σ_{m′} [symbol] _{M(n)\m}L_{m→n}′(xₙ) for each m ε M(n) (2)

zₙ(xₙ)=L(xₙ|yₙ)+Σₘ [symbol] _{M(n)}L_{m→n}(xₘ) (3)

Decision in Decoding:

If Z(xₙ)≧0, then x̂ₙ=0; and if Z(xₙ)<0, then x̂ₙ=1. Thus a vector x̂=(x̂₀, x̂₁, . . . , x̂_{N-1}) is obtained. If x̂H^{T}=0, the decoding process stops, otherwise, step 1 is repeated. If the number of iterations for decoding reaches a preset maximum value itₘₐₓ but x̂H^{T}=0 cannot be satisfied, then decoding failure is indicated.

To determine an output message from each node during the current iteration, the previous iteration results z_{n→m} and L_{m→n} are received from equations (1) and (2). To store the previous iteration results, memories of (2 dv+1)BN (dv denotes an average degree of node, B denotes a number of bits for a message) bits are required for an LDPC decoder.

In the CN_C BP algorithm, calculation is implemented to focus on the check nodes. The check node messages are updated, and corresponding variable node messages V_Ms are updated after the check node messages are updated. Since the variable node messages are updated immediately after the update of check node messages, the variable node message that has already updated is used for the update of the next check node message (during the same iteration), i.e., the variable node messages are applied in the iteration to speed the message convergence and reduce the number of iterations for decoding. The CN_C BP decoding algorithm is described as follows:

Initialization:

Suppose each V_M correspond to a channel message Ch_M, and messages are 0s.

Message Updating:

Step 1: let m=0;

Step 2: using equation (1), determining the check node message L_{m→n} (xₙ) for each n [symbol] ;

Step 3: using equation (2), updating the variable node message z_{n→j}(xₙ) for each n [symbol] M(m) and j [symbol] N(n)\m; calculating zₙ(xₙ);

Step 4: m++; if m=M−1, one iteration process is completed; and if m<M−1, go to step 2.

Decision in Decoding:

If Z(xₙ)≧0, then x̂ₙ=0, and if Z(xₙ)<0, then x̂ₙ=1. Thus a vector x̂=(x̂₀, x̂₁, . . . , x̂_{N-1}) is obtained. If x̂H^{T}=0, the decoding process stops, otherwise step 1 is repeated. If the number of iterations reaches the preset maximum value itₘₐₓ and x̂H^{T}=0 cannot be satisfied, then decoding failure is indicated.

To further reduce an amount of memory for LDPC decoding, a variable node message vector is proposed for variable node message storing and updating, as shown in FIG. 2. A first bit 201 corresponds to a hard decision bit of a variable node. The sequent Ch_M 202 (B bits) corresponds to a channel message of the variable node. A VM_E 204 indicates the variable node's extrinsic message (V_M) that updates and stores messages. A VN_F 203 indicates a variable node mark that controls an iterative decoding process.

With VN_M, using equation (4) the variable node message transmitted to the i^{th} (i=0,1, . . . , dᵥ−1) check node is

V_{—}M(i)=VM_{—}E(i)+Ch_{—}M (4)

A hard decision message (D_M) corresponding to the variable node can be determined using equation (5):

D_{—}M=Ch_{—}M+(Σᵢ [symbol] _{{0, 1 . . . , dv-1}}VM_{—}E(i))/(dᵥ−1 (5)

For the variable node v connecting with dᵥ checking nodes c₀, c₁, . . . , c_{dv-1}, the messages transmitted to the check nodes during iteration it are defined as C_M (it, 0), C_M (it, 1), . . . , C_M(it, dᵥ−1). The variable node extrinsic messages are defined as VM_E (it,0), VM_E(it, 1), . . . , VM_E(it, dᵥ−1). If the check node message C_M(it, j) corresponding to cⱼ is updated to C_M(it+1, j) through iteration it+1, then according to an update rule , the variable node message vector can be updated using equation (6) for j [symbol] {0, 1, . . . , dᵥ−1} and k [symbol] N(v)\k.

VM_{—}E(it+1, k)=C_{—}M(it+1,j)+VM_{—}E(it, k)−(Σₗ [symbol] _{N(v)\j}VM_{—}E(it, l)−(dᵥ−2) VM_{—}E(it, j))/(dᵥ−1) (6)

As described above, a conventional BP algorithm stores previous iteration results so that an increased amount of memory is necessary. In addition, in the conventional BP algorithm, each check node is processed as a subcode. Since a subcode has fewer codeword bits, information converges slowly in the iteration. However, with a trigger-scheduled updating of a variable node message in the CN_C BP algorithm, the update of a sequent check node message utilizes the variable node message so that the convergence is fast. In addition, the CN_C BP algorithm based on variable node message vector requires a reduced amount of memory.

Therefore a need exists for a method and device for reducing decoding complexity and number of iterations for a low density parity check code.

### SUMMARY OF THE INVENTION

An aspect of the present invention is to address at least the above-mentioned problems and/or disadvantages and to provide at least the advantages described below. Accordingly, an aspect of the present invention is to provide a method for decoding a Low Density Parity Check (LDPC) based on a variable node message vector and a CN_C BP algorithm and also a decoder using the decoding method. With the proposed decoding method and the corresponding decoder, superior performance and fast convergence can be obtained.

In accordance with an aspect of present invention, an apparatus for decoding an LDPC is provided. The apparatus includes a variable node message memory for storing a variable node message vector; a memory access controller for controlling a node computing unit to read from and write to the variable node message memory and for controlling an iteration process for the apparatus, a node computing unit for updating a check node message and a variable node message, and for determining a decision message, the node computing unit comprising a variable node message generation unit for determining the variable node message for use in a check node message calculation unit according to the variable node message vector, a check node message calculation unit for updating the check node message, a variable node message updating unit for updating a corresponding variable node message, a hard decision calculation unit for determining the hard decision message for a corresponding variable node, and a parity check unit for calculating a parity bit and for outputting the parity bit results to a decoding termination controller.

In accordance with another aspect of present invention, a method for decoding an LDPC is provided. The method includes initializing an address table, a node computing unit and a variable node message memory, reading a variable node message vector, updating a check node message and the variable node message, and determining a hard decision message, and controlling an iteration process of LDPC decoding in response to a decoding termination control signal or outputting the decoding termination control signal according to a preset maximum number of iterations, wherein the reading of the variable node message vector further comprises determining the variable node message applied in the check node message calculation unit according to the variable node message vector, updating the check node messages, updating corresponding variable node message, determining the hard decision message for corresponding variable nodes, determining a check bit and outputting the check bit result to the decoding termination controller.

Other aspects, advantages and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 is a two-section figure for LDPC code according to the conventional art;

FIG. 2 is a schematic diagram of variable node memory vector according to the conventional art;

FIG. 3 illustrates a generalized block diagram of an LDPC decoder according to an exemplary embodiment of the present invention;

FIG. 4 illustrates a structure of a decoder based on CN_C BP algorithm and variable node message vector according to an exemplary embodiment of the present invention;

FIG. 5 illustrates a flow diagram of LDPC decoding according to an exemplary embodiment of the present invention;

FIG. 6 illustrates a block diagram of a node computing unit according to an exemplary embodiment of the present invention;

FIG. 7 illustrates a flowchart for determining a node according to an exemplary embodiment of the present invention

FIG. 8 illustrates a block diagram of a variable node message generation unit according to an exemplary embodiment of the present invention;

FIG. 9 illustrates a block diagram of a variable node message vector updating unit according to an exemplary embodiment of the present invention;

FIG. 10 illustrates a block diagram of a hard decision calculation unit according to an exemplary embodiment of the present invention;

FIG. 11 illustrates a block diagram of a parity verification unit according to an exemplary embodiment of the present invention;

FIG. 12 illustrates a floating-point performance curve of N_C BP algorithm according to an exemplary embodiment of the present invention;

FIG. 13 illustrates a seven-bit fixed-point performance curve of N_C BP algorithm according to an exemplary embodiment of the present; and

FIG. 14 illustrates a diagram comparing an average number of iterations of CN_C BP algorithm according to an exemplary embodiment of the present.

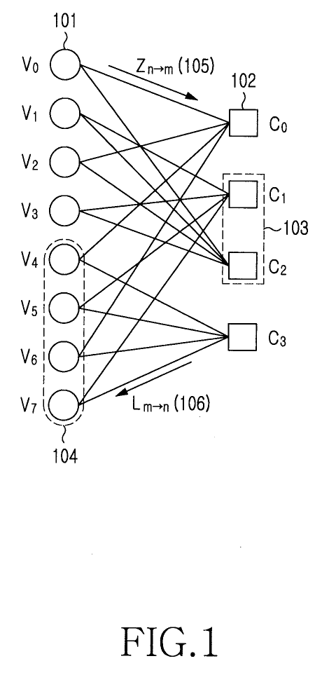

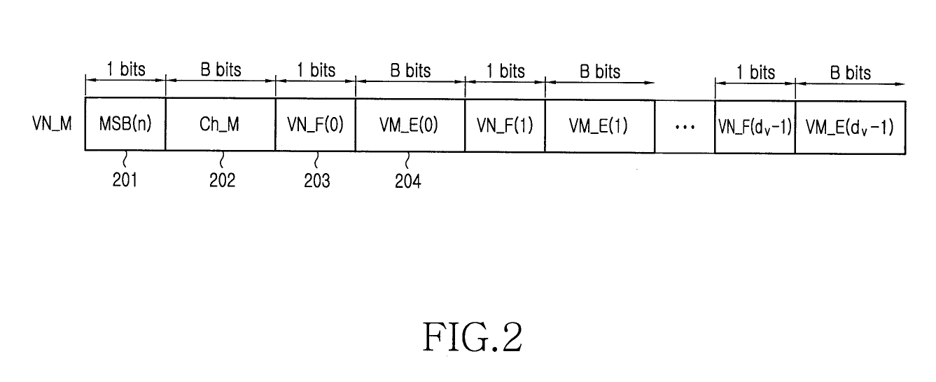

Throughout the drawings, it should be noted that like reference numbers are used to depict the same or similar elements, features, and structures.

### DETAILED DESCRIPTION OF EXEMPLARY EMBODIMENTS

The following description with reference to the accompany drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention are provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to skill in the art, may occur in amounts that do not preclude the effect the characteristic was intended to provide.

An exemplary embodiment of the present invention includes a novel Low Density Parity Check (LDPC) code decoder based on a variable node message vector and a Check Node Central Belief Propagation (CN_C BP) algorithm to obtain superior performance with reduced memory of messages inside the LDPC decoder and a number of average iterations.

In the following, an LDPC with a ½ code rate is taken to illustrate an operation process of the LDPC decoder.

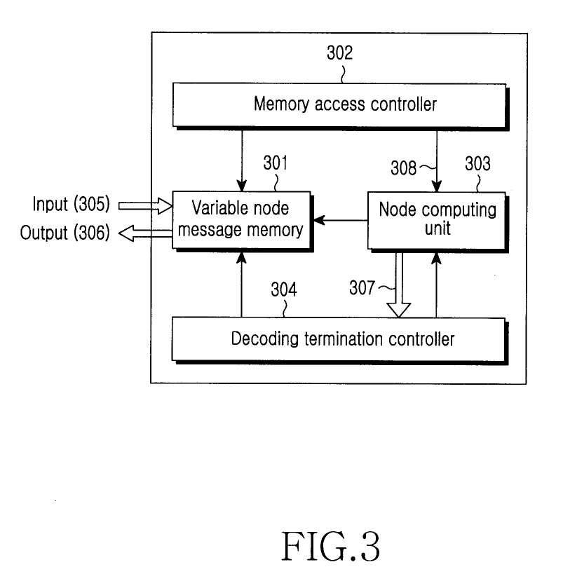

An exemplary structure of the LDPC decoder is illustrated in FIG. 3. The decoder may include a variable node message memory 301, a memory access controller 302, a node computing unit 303 and a decoding termination controller 304. The channel information vector is input 305 into the decoder, which outputs 306 hard decision codeword bits. In FIG. 3, arrows 307, which are thick, represent data streams and arrows 308 represent control signals. The functions of the LDPC decoder units are as follows:

Referring to FIG. 3, the variable node message memory 301 stores a variable node message vector. Under the control of the memory access controller 302, the node computing unit 303 may implement read and write operations to the variable node message memory 301. For example, the variable node message memory 301 stores 9216 variable node message vectors from the memory access controller 302.

The memory access controller 302 controls the node computing unit 303 to implement read and write operations to the variable node message memory 301.

Still referring to FIG. 3, the decoding termination controller 304 determines the decoding termination control signal from the node computing unit or outputs the decoding termination control signal according to a preset maximum number of iterations to control an iteration process of LDPC decoding.

The node computing unit 303 implements operations for updating check node messages or variable node messages and determining a decision message and the like.

The LDPC decoder, based on the CN_C BP algorithm and variable node message vector is described below.

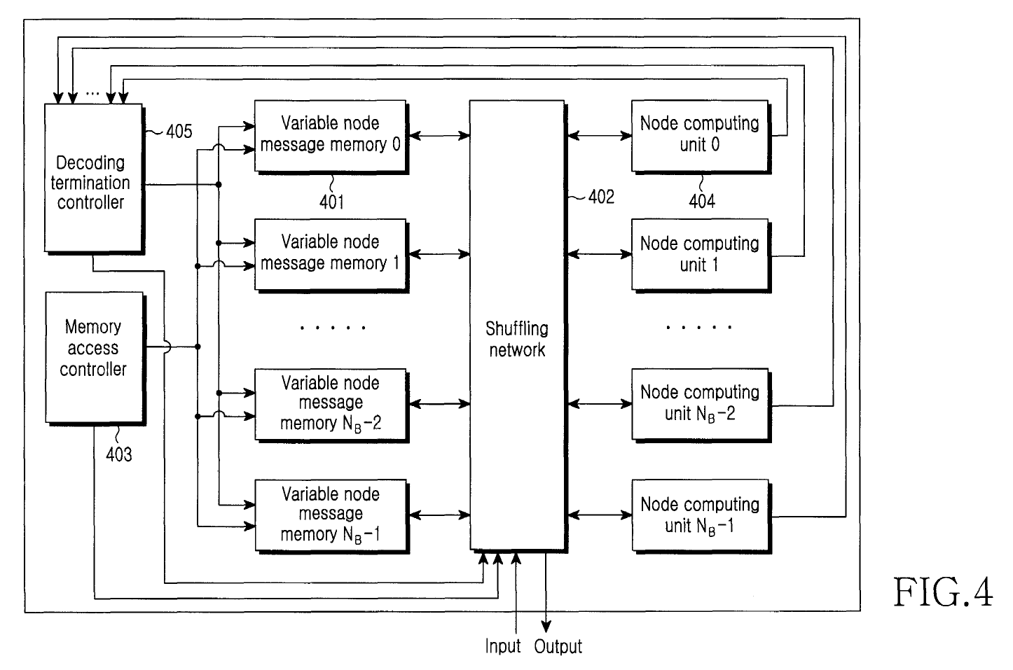

FIG. 4 illustrates a detailed block diagram of the LDPC decoder, where N_{B} includes a number of parallel branches of the LDPC decoder. In general, N_{B} is an integer that may be divided by a number of check nodes M. In FIG. 4, if N_{B}=1, the LDPC decoder has a full serial-structure, if N_{B}=M, the LDPC decoder has a full parallel-structure, and if N_{B} is any of other values, the decoder has a block-level parallel structure or a sub-block-level parallel structure. The N_{B} should be specified to meet the LDPC decoder demands throughput.

As shown in FIG. 4, a variable node message memory 401 (VN_M RAM) and a shuffling network (Π) 402 include a variable node message storage. The VN_M RAM is used to store a variable node message vector and the shuffling network (Π) 402 provides an interface between node computing units (N_CMP) and the VN_M RAM. The N_{B} N_CMP units feed check results back to a decoding termination controller 405. And, according to the feedback results, the decoding termination controller 405 controls a time the LDPC decoder outputs decoded bits.

An LDPC code is adopted by a Satellite Terrestrial Interactive Multi-service Infrastructure (STiMi) in which a codeword length N=9216 and a number of parity check bits M=4608. If N_{B}=16, then the N_{B} includes 16 branches that are simultaneously implemented in parallel in the LDPC decoder.

In FIG. 4, 16 variable node message memories 401 store 576 variable node message vectors. A mapping relationship among the shuffling networks (Π) 402 is specified by a check matrix for the LDPC code. The LDPC decoder's message storing means includes the variable node message memory 301 and the shuffling network (Π) 402. Under the control of the memory access controller 403, the node computing unit 404 may perform reading and writing operations to the message storing means. The 16 node computing units 403 feed parity check results back to the decoding termination controller 405. According to the results, the decoding termination controller 405 controls a time for the decoder to output the decoded bits.

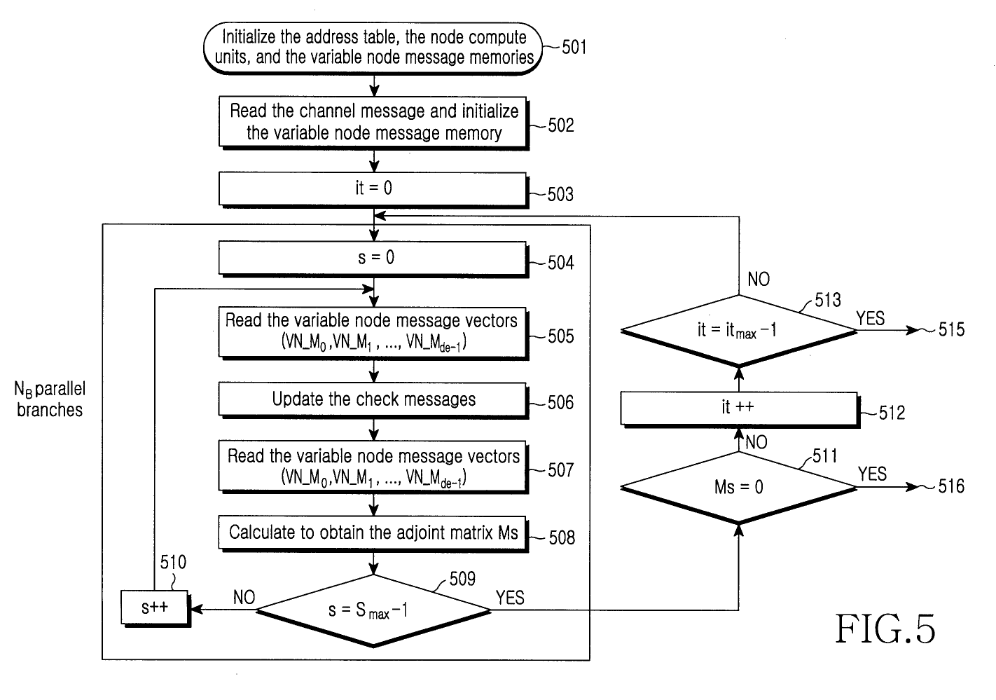

FIG. 5 is a flowchart illustrating an LDPC decoding method according to an exemplary embodiment of the present invention. Variables used in the flowchart are as follows:

It is a current number of iterations;

s is a current number of intrinsic iterations;

Sₘₐₓ is a maximum number of intrinsic iterations, i.e., M/N_{B};

Ms is an adjoint matrix of a current codeword, i.e., x̂H^{T};

As illustrated in FIG. 5, an LDPC iteration process begins with an extrinsic decoding start signal indicator. In step 501, relevant address tables, counters and intrinsic registers in the decoder are initialized. In step 502, channel information is read and a variable node message memory (VN_M RAM) is initialized. In step 503, it=0 and s=0 in step 504. Also, in step 504, N_{B}=16, where N_{B} is a number of parallel branches that operate simultaneously. In step 505, a variable node message vector is read for calculation. In this case, an iterative decoding operation is implemented with a focus on a check node and a current calculation is based on one check node. Accordingly, an applied variable node message vector corresponds to variable nodes connecting with the check node.

Further, in step 506 check node messages are updated. The variable node message vector is read in step 507. In step 508, the adjoint matrix Ms is computed. In step 509, if s=Smax−1, the process proceeds to step 511, otherwise, the process proceeds to step 510. In step 510 the number of intrinsic iterations is increased (s++) and the process returns to step 505. In step 511, if Ms equals 0, the decoding process is terminated and the decoded bits are output in step 516. Otherwise, if Ms does not equal 0, the process proceeds to step 512. In step 512, the current number of iterations is increased (it++). In step 513, if it=itₘₐₓ−1, the decoding process is terminated and the decoded bits are output in step 515. Otherwise, if it is not equal to itₘₐₓ−1, the process returns to step 504.

In the description above, the LDPC decoder, based on a variable node message vector and the CN_C BP algorithm, an implementation scheme for the LDPC decoder is given. In an exemplary implementation, the description is focused on the implementation method and means for the node computing unit 303 using function modules, such as the memory access controller, the decoding termination controller and the variable node message memory. However, the present invention is not limited thereto. Accordingly, any available method may implement the function modules.

An updating of check node messages and the updating of variable node messages are implemented in the node computing unit 303. The node computing unit 303 is a critical component of the LDPC decoder. The node computing unit 303 is designed based on the method of storing and updating the variable node message vector.

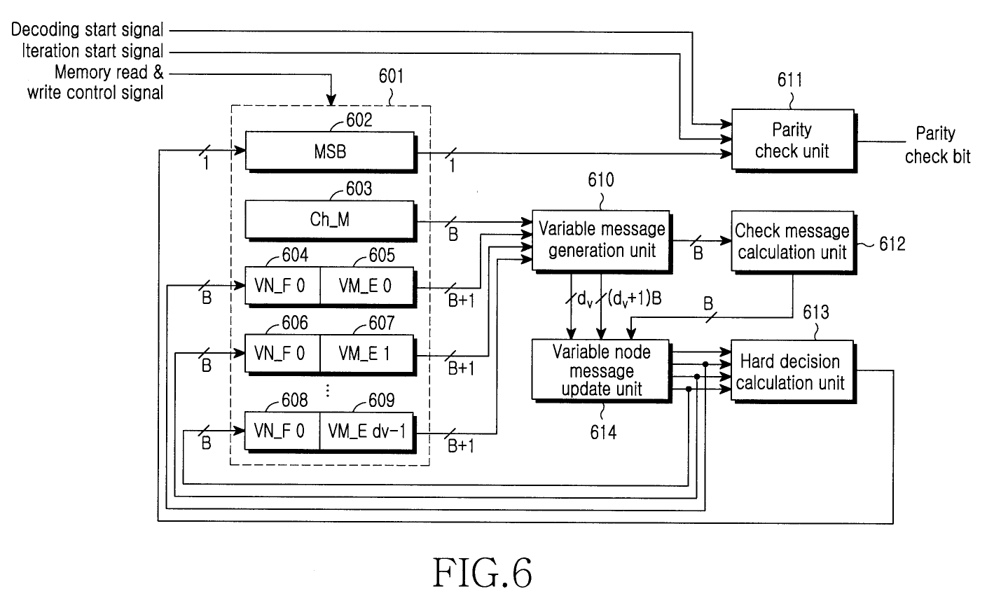

An exemplary structure of the node computing unit 303 is illustrated in FIG. 6. The node computing unit 303 includes a variable message generation unit (V_M_Gnrt) 610, a check node calculating unit (C_M_Calc) 612, a variable node message updating unit (VN_M_Updt) 614, a hard decision calculating unit (H_D_Calc) 612 and a parity check unit (Prt_Chk) 611. A dashed line block on the left of FIG. 6 represents a temporary variable node memory unit (VN_M RAM) 601. A decoding start signal, an iteration start signal and a memory read and write control signal are extrinsic control signals to the node computing unit 303 and control the node computing unit 303. Functions of the node computing unit 303 components are described below.

In FIG. 6, the variable message generation unit 610 determines the variable messages applied in a check message calculation unit 612 according to the variable node message vector. The check message calculation unit 612 updates check messages using equation (1) or any one of equations (2)-(6). The variable node message updating unit 614 updates corresponding variable node messages. The hard decision calculation unit 613 determines hard decision messages for corresponding variable nodes.

Still referring to FIG. 6, the parity check unit 611 determines parity check bits and outputs the results to a decoding termination controller. The parity check bits are different from parity check bits coded during a coding process. The parity check bits refer to check results of a check equation in a corresponding LDPC check matrix.

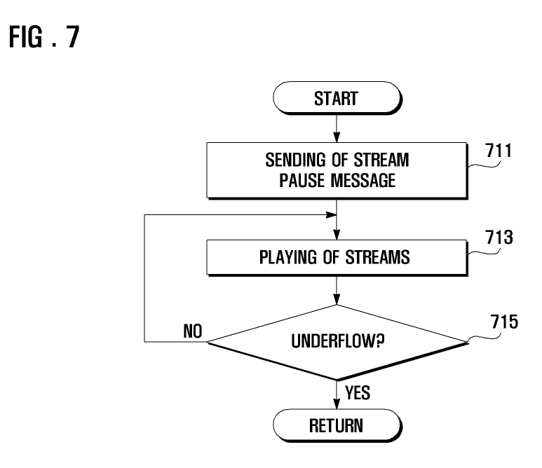

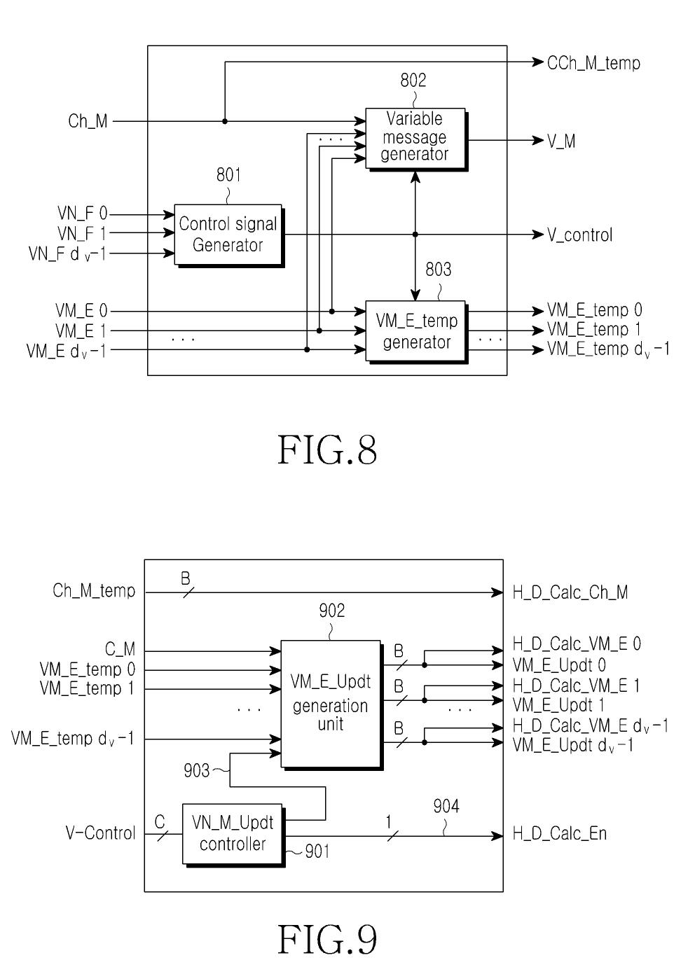

A flowchart of a determination period implemented in a node computing unit 303 is illustrated FIG. 7. The flowchart illustrates a process of updating messages between one check node and the variable nodes connecting with the check node. The node computing unit 303 is simultaneously under the control of a decoding start signal and an iteration start signal. When the decoding start signal and the iteration start signal are enabled, the node computing unit 303 is in service. The termination signal becomes a low level signal on a falling edge of the iteration start signal. That is, if the termination signal is in a low level signal, previous iterative decoding succeeds and the iteration process should be terminated. If the termination signal is in the high level, the iteration process continues until a number of iterations reach a present maximum value.

In an STiMi, indices of variable nodes connecting with the first check node are specified by the check matrix of the LDPC with a ½ code rate as 0, 6, 12, 18, 25 and 30. With reference to FIG. 7, an operation flow in the node computing unit 303 is described below.

Referring to FIG. 7, in step 701 registers inside the node computing unit 303 are initialized. In step 702 j=0. In step 703 a current variable node message vector VN_M j indexed by 0, 6, 12, 18, 25 and 30 is read. In step 704 variable message V_M j is determined. In step 705 if j equals d_{c}−1, the process proceeds to step 707. Otherwise, if j does not equal d_{c}−1, the process proceeds to step 706. In step 706 j is increased (j++) and the process returns to step 703. In step 707 a parity checking process is performed and then a current check message is determined in step 708.

Still referring to FIG. 7, in step 709 j=0. In step 710 the variable node message vector VN_M j is updated. In steps 711 and 712 the variable node message vector VN_M j is written into the variable node message vector memory VN_M RAM and a hard decision determination is performed, respectively. In step 713 if j=d_{c}−1, the process proceeds to step 714. Otherwise, if j does not equal d_{c}−1, the process proceeds to step 715. In step 714 j is increased (j++) and the process proceeds to step 710. In step 714 the node computing process is completed.

After step 715, the decoder determines a next check node, stops current iteration and starts the next iteration, or completes an entire decoding process. In an exemplary implementation, operations of reading and writing the VN_Ms are implemented in serial and may be implemented in parallel after some modifications to the node computing unit 303.

The variable message generation unit (V_M_Gnrt) 610 generates variable messages necessary for updating a check message and a variable node message. For example, an index of the check node that is currently processed is denoted as i_Cur_CN. A variable node's variable node mark (VN_F) in a corresponding message vector of the variable node connecting with the check node equals 1. Here, i_Cur_CN also indicates an index of N_F whose value is 1, i.e., VN_F(i_Cur_CN)=1. Subscripts of VN_F, whose value is 1, are different from each other for different variable node message vectors. However, the subscripts correspond to the index of the check node currently being processed.

Here, i_Cur_CN=0. The indication signals VN_F(O)˜VN_F(2) for six variable node message vectors connecting with the check node are 100,100,100,100,100,100, respectively.

The variable message generation unit 610 includes a control signal generator 801, a variable message generator 802 and a temporary variable node extrinsic message (VM_E_temp) generator 803.

The control signal generator 801 determines the variable message after a node control signal V_control is generated. The control signal V_control is received according to a dᵥ variable node, which is a vector of dᵥ bits, marked VN_F (0)˜VN_F (dᵥ−1) of each VN_M.

Accordingly, the control signal V_control is determined according to three node marks VN_F (0)˜VN_F (2) in each VN_M., which is a 3-bit vector.

The V_control signal indicates the index of the check node in processing. With the control signal V_control, the variable message generator 610 and the VM_E_temp generator 803 select an appropriate VM_E from VN_M. Meanwhile, the control signal V_control is transmitted to a VN_M_Updt unit.

The variable message generator is used to determine variable messages using equation (4). A current variable node extrinsic message VM_E implements a control function with the V_control signal, i.e., VM_E(i_Cur_CN). The obtained V_M is a message transmitted to a current check node i_Cur_CN from the variable node.

The VM_E currently used and controlled by the control signal V_control are selected to determine VM_E(0) using equation (4). The determined V_M is a message transmitted from the variable node to the check node 0.

A temporary variable node extrinsic message generator is used to generate a VM_E_temp message for the VN_M_Updt unit. During the process of generating the temporary variable node extrinsic message with a variable node extrinsic message, the VM_E_temp (i_Cur_CN) remains unchanged. Here, the input channel information Ch_M is used as the temporary channel information Ch_M_temp signal to be transmitted to the VN_M_Updt unit.

The variable VM_E_temp(0) remains unchanged and the Ch_M_temp signal is transmitted to the VN_M_Updt unit.

The check message calculation unit 612 is used for updating the check messages. Two implementation structures may be applied in the check message calculation unit 612. One implementation structure includes a serial structure and another implementation structure includes a parallel structure. In the parallel structure, the determination process does not start until all d_{c}(=6) variable messages have reached the check message calculation unit 612 and any of the methods for updating the check message may be applied.

The variable node message updating (VN_M_Updt) unit performs an update of the variable node message vector. As shown in FIG. 9, the variable node message updating unit primarily consists of two parts: a VN_M_Updt controller 901 and a VM_E_Updt generation unit 902.

The VN_M_Updt controller receives a V_control signal. From the VN_M_Updt controller, two control signals are output. One control signal 903 (a dᵥ-bit vector (=3-bit vector)) is transmitted to a VM_E_Updt generation unit 902, and another control signal 904 (a one-bit signal) is transmitted to a hard decision calculation unit H_D_Calc. The hard decision calculation enable signal H_D_Calc_En is consistent with the VN_F (dv−1(=2)). If VN_F (dv−1)=1, the H_D_Calc_En is enabled.

In this case, the VN_F(2)s corresponding to six variable nodes all equal 0. Thus, H_D_Calc_En is disabled. If the index of a determined check node is 2 (and the indices of the corresponding variable nodes are 0, 8, 13, 20, 32 and 8270), the node mark VN_F (0)˜VN_F (2) of variable node message vector zero is 001. Accordingly, H_D_Calc_En is disabled.

Inputs of the VM_E_Updt generation unit 902 are check nodes (C_M) and VM_E temp signals, from which an updated variable node extrinsic message signal VM_E_Updt is output. The control signal is used to determine and select a correct VM_E_temp signal for current updating. That is, the update is implemented using equation (6) with the index i_Cur_CN and VM_E_Temp unchanged. More specifically, VM_E temp has been determined in the V_M_Gnrt unit. Therefore, the addition operation is used for the determination update. The VM_E_Updt generation unit writes VM_E_Updts back into the VN_M memory and transmits the VM_E_Updt (which is re-stated as H_D_Calc_VM_Es) to the H_D_Calc unit to determine a decision message. Meanwhile, the Ch_M temp (which is re-stated as H_D_Calc_Ch_M) is transmitted to the H_D_Calc unit.

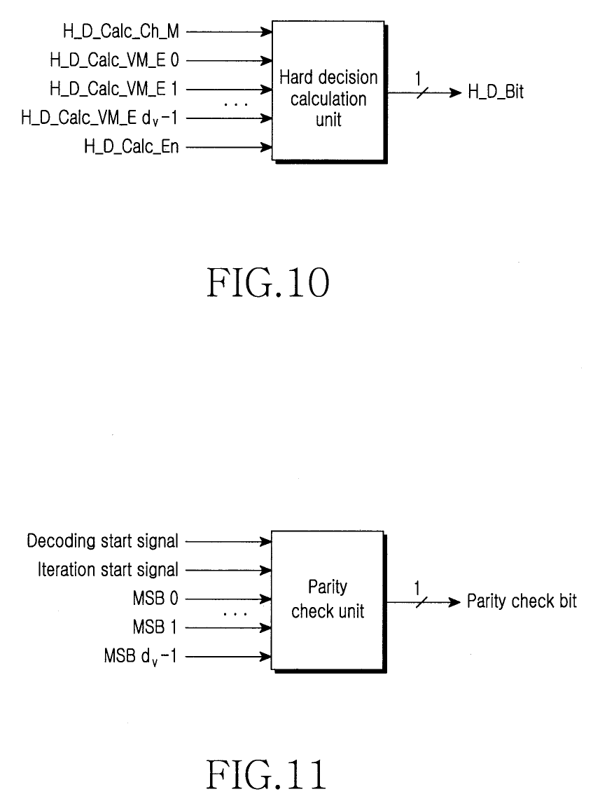

In FIG. 10, the hard decision calculation unit 613 is used for determining a variable node hard decision message and outputting hard decision bits. If the signal H_D_Calc_En becomes a high level signal, the hard decision calculation unit 613 starts to operate. The hard decision calculation unit 613 determines the hard decision message D_M for a variable node using equation (7) and outputs a Most Significant Bit (MSB) (which indicates the sign of M_M) of D_M. The hard decision results related to the sign bit and the updated variable message vectors are written back into the VN_M memory. If the determination result of a current check node is 0, the hard decision calculation unit 613 does not work.

D_{—}M=H_{—}D_Calc_Ch_{—}M+(Σᵢ [symbol] _{{0, 1, . . . , dv-1}}H_{—}D_Calc_{—}VM_{—}E(i))/(dᵥ−1) (7)

Under the control of the decoding start signal and the iterating start signal, in FIG. 11, the parity check unit 611 determines whether the check equations are satisfied for current check points. The parity check unit 611 operates in parallel with a check message updating unit by outputting a parity check bit to indicate whether the parity check equation is satisfied. The output results are transmitted to the decoding termination controller. If the parity check equations are satisfied, the decoding process is correct and then finished.

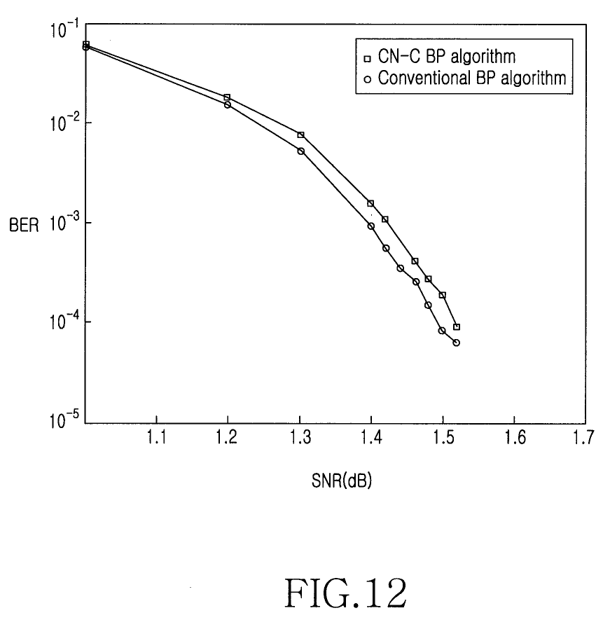

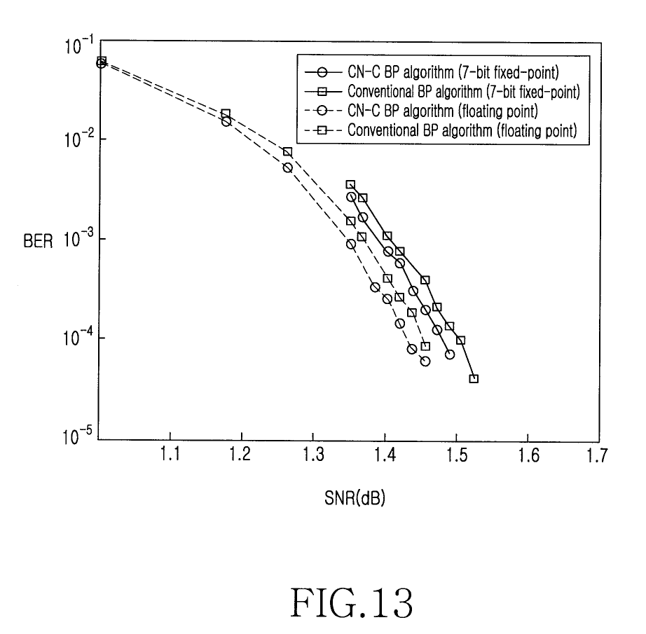

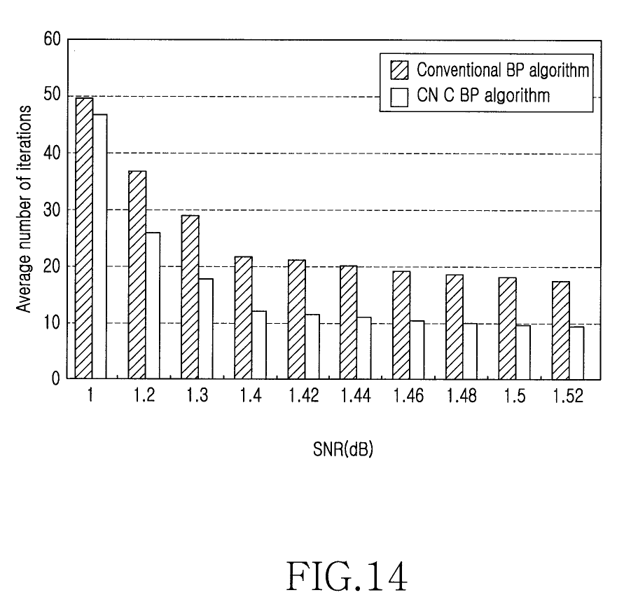

In an exemplary implementation, performance simulations are performed to the LDPC decoder in order to achieve better performance. An average iteration number is reduced by approximately one half. A floating point and fixed point Bit Error Rate (BER) performance curves are respectively given in FIG. 12 and FIG. 13. Here, Signal-to-Noise Ratio (SNR) refers to Eb/N0, the modulation scheme includes a Binary Phase Shift Keying (BPSK) and a channel includes a Gaussian model. For comparison, performance of the decoder based on the conventional BP algorithm is also given in FIGS. 12 and 13. In FIG. 14, the average iterations numbers and the conventional BP algorithm are given. From the simulation results, certain conclusions may be drawn as explained below.

Floating point performance curves of CN_C BP algorithm (circle dot) and conventional BP algorithm (square) are illustrated in FIG. 12. The CN_C BP algorithm 7-bit fixed point performance curves (circle dot) and conventional BP algorithm (square) are illustrated in FIG. 13. The performance of the CN_C BP algorithm is better than the performance of the conventional BP algorithm. Accordingly, the CN_C BP algorithm is more effective than the conventional BP algorithm.

The average iterations numbers necessary for CN_C BP decoding and the conventional BP decoding under different signal-to-noise ratios are given in FIG. 14. In this case, the CN_C BP algorithm saves about one half average iterations and obtains better decoding performance.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. An apparatus for decoding a Low Density Parity Check (LDPC), the apparatus comprising:
a variable node message memory for storing a variable node message vector;
a controller for controlling a node computing unit to read from and write to the variable node message memory and for controlling an iteration process for the apparatus; and
a node computing unit for updating a check node message and a variable node message, and for determining a hard decision message, the node computing unit comprising:
a variable node message generation unit for determining the variable node message for use in a check node message calculation unit according to the variable node message vector;
a check node message calculation unit for updating the check node message;
a variable node message updating unit for updating a corresponding variable node message;
a hard decision calculation unit for determining the hard decision message for a corresponding variable node; and
a parity check unit for determining a parity bit and outputting the parity bit result to a decoding termination controller.

2. The apparatus according to claim 1, wherein the variable message generation unit comprises:
a control signal generator for generating a node control signal (V_control);
a variable message generator for selecting a correct variable node extrinsic message (VM_E) to generate the variable node message under control of the generated node control signal; and
a temporary variable node extrinsic message generator for generating a temporary variable node extrinsic message for the variable node message updating unit.

3. The apparatus according to claim 2, wherein the control signal generator generates the node control signal (V_control) according to a variable node mark of each variable node message.

4. The apparatus according to claim 2, wherein the variable message generator generates variable messages using the following equation:
V [symbol] _{—}M(i)=VM_{—}E(i)+Ch_{—}M
wherein, V [symbol] _M(i) comprises a variable node extrinsic message of node i, and Ch_M comprises channel information for a corresponding node.

5. The apparatus according to claim 2, wherein the temporary variable node extrinsic message generator generates a temporary variable node extrinsic message with the variable node extrinsic message.

6. The apparatus according to claim 2, wherein the variable node message updating unit comprises:
a variable node message update controller for controlling the node extrinsic message update generation unit and the hard decision calculation unit with node control signals; and
a variable node extrinsic message update generation unit for updating the variable node extrinsic messages according to a check message (C_M) for a corresponding node and a temporary variable node extrinsic message (VM_E temp) and for transmitting an updated variable node extrinsic messages to the hard decision calculation unit for determining the hard decision message.

7. The apparatus according to claim 6, wherein the variable node extrinsic message update generation unit writes the updated variable node extrinsic message into the variable node message memory and transmits a temporary channel message (Ch_M_temp) to the hard decision calculation unit.

8. The apparatus according to claim 2, wherein a hard decision message (D_M) for the variable node is determined by inputting a hard decision calculation enabling signal (H_D_Calc_En), a channel message (H_D_Calc_Ch_M) and a variable node extrinsic message (H_D_Calc_VM_E) into the hard decision calculation unit, outputting a sign bit of D_M, and writing back the hard decision message and an updated variable node message vector into the variable node message memory.

9. The apparatus according to claim 2, wherein under the control of a decoding start signal and an iteration start signal, the parity check unit determines whether a check equation for a current check node is satisfied, outputs a check bit indicating whether the check equation is satisfied, and transmits a result to a decoding termination controller.

10. The apparatus according to claim 1, wherein the decoding termination controller at least one of receives a termination control signal from the node computing unit and outputs a termination control signal according to a preset maximum number of iterations to control the iteration process for the apparatus.

11. A method for decoding a Low Density Parity Check (LDPC), the method comprising:
initializing an address table, a node computing unit and a variable node message memory;
reading a variable node message vector, updating a check node message and a variable node message and determining a hard decision message; and
controlling an iteration process of LDPC decoding in response to a decoding termination control signal or by outputting the decoding termination control signal according to a preset maximum number of iteration,
wherein the reading of the variable node message vector further comprises:
determining the variable node message according to the variable node message vector;
updating the check node messages;
updating corresponding variable node message;
determining the hard decision message for corresponding variable nodes; and
determining a check bit and outputting the check bit result to a decoding termination controller.

12. The method according to claim 11, wherein the determining of the variable node message vector comprises:
generating a node control signal (V_control);
selecting a correct variable node extrinsic message (VM_E) under the control of the generated node control signal (V_control) to generate a variable message; and
generating a temporary variable node extrinsic message for a corresponding variable node message updating unit.

13. The method according to claim 12, wherein the node control signal (V_control) is generated according to a variable node mark of each variable node message.

14. The method according to claim 12, wherein the variable message is generated by using the following equation:
V [symbol] _{—}M(i)=VM_{—}E(i)+Ch_{—}M
wherein, V [symbol] _M(i) comprises a variable message of node i, and VM_E (i) comprises a variable node extrinsic message of node i and Ch_M comprises a channel message for a corresponding node.

15. The method according to claim 12, wherein the temporary variable node extrinsic message is generated with a variable node extrinsic message.

16. The method according to claim 12, wherein in the updating of the corresponding variable node message comprises:
updating the variable node extrinsic message, according to a check message (C_M) for a corresponding node and the temporary variable extrinsic message (VM_E_temp), in a node extrinsic message update generation unit under control of the node control signal (V_control); and
transmitting the updated variable node extrinsic message to the hard decision calculation unit under control of the node control signal (V_control)for determining the hard decision message.

17. The method according to claim 16, wherein the updated variable node extrinsic message is written back into the variable node message memory and a temporary channel message (Ch_M_temp) is transmitted to the hard decision calculation unit.

18. The method according to claim 12, wherein the determining of the hard decision message comprises:
determining a hard decision message (D_M) for the variable node according to at least one of an input hard decision calculation enabling signal (H_D_Calc_En), a channel message (H_D_Calc_Ch_M) and a variable node extrinsic message (H_D_Calc_VM_E);
outputting a sign bit of D_M; and
writing back the hard decision message and the updated variable node message vector into the variable node message memory.

19. The method according to claim 12, further comprising:
under the control of a decoding start signal and an iteration start signal, determining whether a check equation for a current check node is satisfied;
outputting a check bit indicating whether the check equation is satisfied; and
transmitting the result to the decoding termination controller.
